(19) United States
(12) Patent Application Publication
(10) Pub. No.: US 2015/0035557 A1
(43) Pub. Date: Feb. 5, 2015

(54) ERROR DETECTION CIRCUIT, POWER SOURCE UNIT, AND IMAGE FORMING APPARATUS

(71) Applicant: Sharp Kabushiki Kaisha, Osaka (JP)

(72) Inventor: Yuuki Kozaki, Osaka (JP)

(73) Assignee: Sharp Kabushiki Kaisha, Osaka (JP)

(21) Appl. No.: 14/374,038

(22) PCT Filed: Jan. 9, 2013
(86) PCT No.: PCT/JP2013/050147

§ 371 Date: Jul. 23, 2014

(30) Foreign Application Priority Data
Jan. 25, 2012 (JP) 2012-013014
Mar. 16, 2012 (JP) 2012-059608

(51) Int. Cl. G01R 31/40; G03G 15/16

(52) U.S. Cl. CPC G01R 31/40; G01R 31/02; G03G 15/1605
USPC 324/764.01; 399/66

(57) ABSTRACT

Provided are an error detection circuit, a power source unit, and an image forming apparatus that are capable of detecting a short circuit state and an open circuit state of a power source output.

An error detection circuit (53) includes an open circuit detection portion (531) that is connected to a power source portion (52) outputting a voltage to a capacitive load (62) and that outputs an error signal by determining an output of the power source portion (52) is in an open circuit state when an absolute value of the voltage is more than or equal to a first threshold value; a short circuit detection portion (532) that is connected to the power source portion (52) and that outputs an error signal by determining an output of the power source portion (52) is in a short circuit state when the absolute value of the voltage that the power source portion (52) outputs to the capacitive load (62) is less than or equal to a second threshold value; and a controller (190) that outputs an output instruction signal to the power source portion (52) and causes the open circuit detection portion (531) and the short circuit detection portion (532) to execute a detection operation for detecting the presence or absence of an error in that order.

### TECHNICAL FIELD

The present invention relates to an error detection circuit that detects an error of a power source output, and to a power source unit and an image forming apparatus that are provided with the error detection circuit.

### BACKGROUND ART

An electrophotographic color image forming apparatus, when transferring a toner image to an intermediate transfer member or to a sheet of paper, outputs a high voltage as a transfer voltage from a power source device. In this manner, such an apparatus that outputs a high voltage to a load is configured to detect an output abnormality of a power source device.

For example, the image forming apparatus described in Patent Literature 1 checks occurrence of output short circuit of a high voltage power source, and, when the output short circuit has occurred, in order to secure the safety of a power source device and in order to grasp a reason of the abnormality and remove the reason by stopping the abnormal operation of the entire device, immediately stops the drive of the high voltage power source.

### CITATION LIST

### Patent Literature

Patent Literature 1: Japanese Patent Laid-Open publication No. 2005-117769

### SUMMARY OF INVENTION

### Technical Problem

However, the image forming apparatus described in Patent Literature 1 cannot cope with a case in which an output of the high voltage power source is in an open circuit state. In the case in which the output of the power source device is in the open circuit state and the power source device is provided with a transformer, a high no-load voltage may be generated in general and the deterioration of insulation may occur.

In view of the foregoing, an object of the present invention is to provide an error detection circuit, a power source unit, and an image forming apparatus that are capable of detecting a short circuit state and an open circuit state of a power source output.

### Solution to Problem

An error detection circuit of the present invention is equipped with an open circuit detection portion, a short circuit detection portion, and a controller. The open circuit detection portion is connected to a power source portion outputting a voltage to a capacitive load and outputs an error signal by determining an output of the power source portion is in an open circuit state when an absolute value of the voltage is more than or equal to a first threshold value. The short circuit detection portion outputs an error signal by determining the output of the power source portion is in a short circuit state when the absolute value of the voltage that the power source portion outputs to the load is less than or equal to a second threshold value. The controller outputs an output instruction signal to the power source portion and causes the open circuit detection portion and the short circuit detection portion to execute a detection operation for detecting the presence or absence of an error in this sequence.

In this configuration, the error detection circuit can detect not only a short circuit state but also an open circuit state of the output of the power source portion.

In addition, in a case in which a load that connects the error detection circuit is a capacitive load, a rise time of an output voltage varies according to a state of the load, so that the rise time may take longer. At such a time, if the short circuit detection portion is caused to execute the detection operation for detecting the presence or absence of an error prior to the open circuit detection portion, in a case in which a time when the output voltage is less than or equal to the second threshold value is long, there is a risk that the case may be erroneously detected as a short circuit state. In this configuration, since the detection operation for detecting the presence or absence of an error of the open circuit detection portion is performed before the detection operation for detecting the presence or absence of an error of the short circuit detection portion, even if an error detection of the output of the power source portion is supposedly performed when the output voltage rises, or even if the rise time of the output voltage is long due to the state of the load at that time, the short circuit state will not be erroneously detected. Accordingly, the open circuit state and the short circuit state of the power source portion can be correctly detected.

In the above aspect of the present invention, the controller may preferably cause the open circuit detection portion and the short circuit detection portion to continuously execute the detection operation for detecting the presence or absence of an error.

When the detection operation for detecting the presence or absence of an error of the short circuit detection portion is performed, there is a risk that the short circuit state may be erroneously detected until the output voltage of the power source portion exceeds the second threshold value. In this configuration, since the open circuit state and the short circuit state are continuously checked, the short circuit state can be checked continuously from a state in which the voltage has risen during the check of the open circuit state and has exceeded the second threshold value. Accordingly, without the erroneous detection of the short circuit state, the abnormality check of the output of the power source portion can be ended in a short time.

In the above aspect of the present invention, the controller may preferably cause the open circuit detection portion and the short circuit detection portion to discontinuously execute the detection operation for detecting the presence or absence of an error.

In this configuration, since the short circuit state is checked after the check of the open circuit state is completed, by excluding the output of the power source portion in the open circuit state after the check of the open circuit state, the output of the power source portion can be reliably detected as being in the short circuit state.

In the above aspect of the present invention, the controller may preferably cause the open circuit detection portion to execute the detection operation when a voltage outputted to the capacitive load rises and may preferably cause the short circuit detection portion to execute the detection operation after the absolute value of the voltage exceeds the second threshold value when the voltage outputted to the capacitive load rises.

In this configuration, in a case in which the error detection of the output of the power source portion is performed when the output voltage rises, even if a time when the output voltage is less than or equal to the second threshold value is long because the rise time of the output voltage is long, the case is not erroneously detected as being in the short circuit state. This makes it possible to detect the output abnormality of a power source when the voltage outputted to the load rises, so that an arbitrary process can be performed immediately after the voltage outputted to the load rises.

The power source portion may preferably output a voltage according to a value of an output instruction signal and may preferably output a voltage of a third threshold value set between the first threshold value and the second threshold value when the value of the output instruction signal is equal to a processing threshold value, and the controller may preferably cause the open circuit detection portion to execute the detection operation when the value of the output instruction signal is less than the processing threshold value and may preferably cause the short circuit detection portion to execute the detection operation when the value of the output instruction signal is more than or equal to the third threshold value.

In this configuration, the open circuit state is checked when the output instruction signal is less than the third threshold value, and the short circuit state is checked when the output instruction signal is more than or equal to the third threshold value. Accordingly, without measurement of the output voltage of the power source portion, the open circuit state and the short circuit state of the power source can be reliably detected.

In the above aspect of the present invention, the error detection circuit may preferably be equipped with a gate section. The gate portion may preferably output a logical sum signal of the output of the open circuit detection portion and the output of the short circuit detection portion to the controller.

In this configuration, the gate portion collects the output of the open circuit detection portion and the output of the short circuit detection portion into one and outputs the collected output, so that the number of output terminals of a signal can be reduced.

In the above aspect of the present invention, the error detection circuit may preferably be equipped with a first switch and a second switch. The first switch may preferably connect or separate the open circuit detection portion to or from the gate portion. The second switch may preferably connect or separate the short circuit detection portion to or from the gate portion. The controller may preferably control the first switch and the second switch.

In this configuration, the controller controls the first switch and the second switch and performs the check of the open circuit state and the short circuit state. This makes it possible to correctly detect whether the output of the power source portion is in the open circuit state or in the short circuit state and to also perform a process according to a detection result.

In the above aspect of the present invention, the error detection circuit may preferably be equipped with a switch. This switch may preferably connect or separate the short circuit detection portion to or from the gate portion. The controller may preferably control this switch.

In this configuration, by setting the switch in a separate state, the output of the open circuit detection portion can be checked, and, by setting the switch in a connected state, the outputs of the open circuit detection portion and the short circuit detection portion can be checked. While the open circuit state and the short circuit state of the output of the power source portion are checked in this sequence, the output in the open circuit state is excluded, so that a signal is not outputted from the open circuit detection portion when the output of the short circuit detection portion is checked, and thus only the short circuit state can be checked. Accordingly, the number of components or a method of control can be simplified.

### Advantageous Effects of Invention

According to preferred embodiments of the present invention, a short circuit state and an open circuit state of a power source device can be detected.

### BRIEF DESCRIPTION OF DRAWINGS

FIG. 1 is a configuration diagram of an image forming apparatus according to a preferred embodiment of the present invent ion.

FIG. 2 is a block diagram of the image forming apparatus according to the preferred embodiment of the present invention.

FIG. 3 is an enlarged view of a secondary transfer region of an image forming portion.

FIG. 4 a circuit diagram of a power source unit.

FIG. 5A is a time chart in a case of performing open circuit detection continuously following short circuit detection. FIG. 5B is a time chart in a case of performing the short circuit detection continuously following the open circuit detection.

FIG. 6 is a flow chart illustrating an error detection process of an output of a power source portion.

FIG. 7 is a circuit diagram of a power source unit different from the power source unit illustrated in FIG. 4.

FIGS. 8A to 8D are time charts in a case of performing the short circuit detection discontinuously following the open circuit detection. FIG. 8A shows a value of an output instruction signal, FIG. BB shows a secondary transfer output voltage, FIG. 3C shows an error signal in an open circuit state, and FIG. 8D shows an error signal in a short circuit state.

FIG. 9 is a flowchart illustrating an error detection process of the power source unit shown in FIG. 7.

FIG. 10 is a circuit diagram of a power source unit different from the power source unit shown in FIG. 7.

### DESCRIPTION OF EMBODIMENTS

A description will be made of an error detection circuit according to preferred embodiments of the present invention, and a power source unit and an image forming apparatus that are equipped with such an error detection circuit.

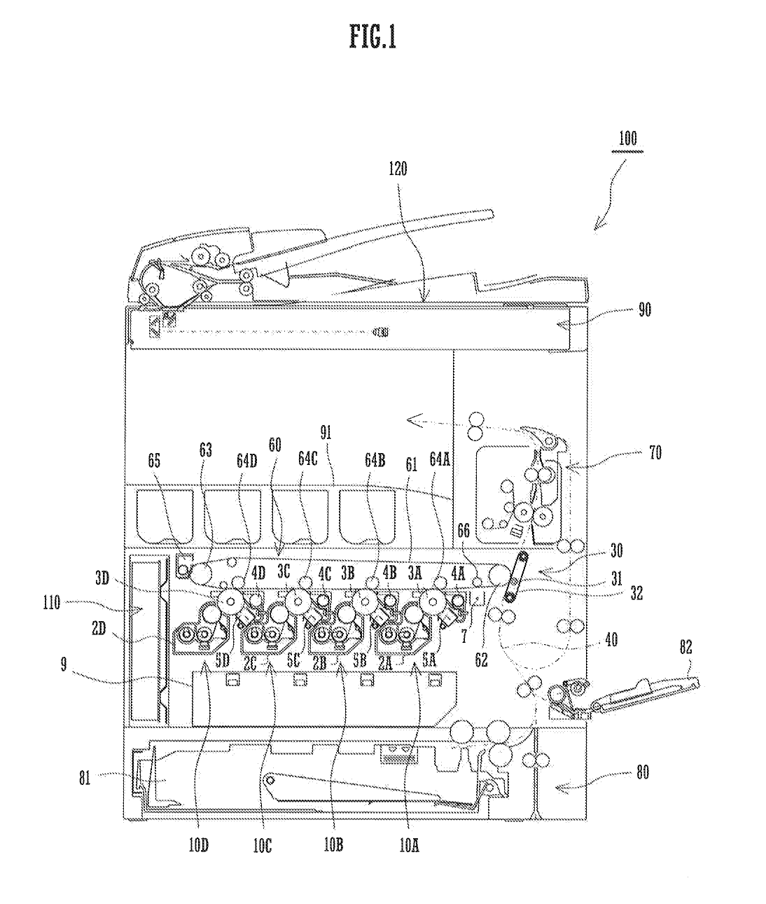

As shown in FIG. 1, an image forming apparatus 100 is equipped with a paper supply portion 80, an image reading portion 90, and an image forming portion 110. The image forming apparatus 100 is also equipped with a panel unit 120 above the image reading portion 90. The panel unit 120 is equipped with a display portion 130 and an operating portion 140 that are not illustrated. The display portion 130 displays information that is notified to a user. The operating portion 140 receives an operation of a user.

The image forming apparatus 100 is configured to perform an electrophotographic polychrome or monochrome image forming process on a sheet of paper as a recording medium based on image data of a document read by the image reading portion 90 or image data inputted from an external device via a communication portion 180 to be described below.

The image forming portion 110 is equipped with an exposure unit 9, image forming units 10A to 10D, an intermediate transfer unit 60 and a secondary transfer unit 30 as transfer portions, a fixing unit 70, and a power source unit 51 to be described below.

The image forming unit 10A is equipped with a developing device 2A, a photoreceptor drum 3A, a cleaner unit 4A, and a charger 5A, and is configured to form an image of black (hereinafter referred to as “K”). The charger 5A is configured to charge the surface of the photoreceptor drum 3A to a predetermined potential uniformly. The developing device 2A is configured to visualize an electrostatic latent image formed on the photoreceptor drum 3A by the exposure of the exposure unit 9, into a K toner image. The cleaner unit 4A is configured to collect residual toner remaining on the peripheral surface of the photoreceptor drum 3A. The image forming units 10B to 10D have the same configuration as the image forming unit 10A and are configured to form a toner image of cyan (hereinafter referred to as “C”), magenta (hereinafter referred to as “M”), and yellow (hereinafter referred to as “Y”), respectively, on the surfaces of the photoreceptor drums 3B to 3D.

The exposure unit 9 is a laser scanning unit including optical components such as a semiconductor laser, a polygon mirror, an fθ lens, and a reflecting mirror. The exposure unit 9 is configured to expose the photoreceptor drums 3A to 3D of the respective image forming units 10A to 10D to laser beams modulated according to image data items corresponding to Y, M, C, and K and scans the surfaces of the respective photoreceptor drums 3A to 3D in the axial direction to form respective electrostatic latent images.

The intermediate transfer unit 60 includes an intermediate transfer belt 61, a driving roller 62, an idle roller 63, primary transfer rollers 64A to 64D, a cleaning unit 65, a pre-transfer charger 7, and a counter roller 66. The intermediate transfer belt 61 is stretched over the driving roller 62, the idle roller 63, and the counter roller 66 and moves along a circulation path that passes through the image forming units 10D, 10C, 10B, and 10A in this sequence. The respective primary transfer rollers 64A to 64D are arranged to be opposed to the photoreceptor drums 3A to 3D across the intermediate transfer belt 61, and the toner images formed on the peripheral surfaces of the respective photoreceptor drums 3A to 3D are primarily transferred onto the surface of the intermediate transfer belt 61. When the toner images are transferred, a transfer voltage is applied between the photoreceptor drums 3A to 3D and the opposed primary transfer rollers 64A to 64D.

In a color image forming process, while the intermediate transfer belt 61 moves along the circulation path, the Y, M, C, and K toner images are sequentially transferred onto the surface of the intermediate transfer belt 61 in an overlaying manner. In a monochrome image forming process, while the intermediate transfer belt 61 moves along the circulation path, only the K toner image is transferred onto the surface of the intermediate transfer belt 61.

The pre-transfer charger 7 is a corona discharge device and is configured to apply a charge of the same polarity as the toner to the toner image on the intermediate transfer belt 61.

The secondary transfer unit 30 is equipped with a secondary transfer roller 31 and a secondary transfer belt 32. The secondary transfer belt 32 is stretched over a plurality of rollers and moves along a predetermined circulation path. The secondary transfer roller 31 is arranged to be opposed to the driving roller 62 across the secondary transfer belt 32 and the intermediate transfer belt 61. The secondary transfer unit 30 secondarily transfers the toner image of the surface of the intermediate transfer belt 61 to a sheet of paper that has been fed to a secondary transfer position between the intermediate transfer belt 61 and the secondary transfer belt 32. The toner image on the intermediate transfer belt 61 is transferred onto the sheet of paper by an electrostatic force at the secondary transfer position. The toner remaining on the surface of the intermediate transfer belt 61 after secondary transfer is collected by the cleaning unit 65.

The fixing unit 70 is configured to heat and pressurize the sheet of paper that has passed through the secondary transfer position and bears the transferred toner image and to fix the toner image to the surface of the sheet of paper. The sheet of paper having passed through the fixing unit 70 is discharged to a paper discharge tray 91.

The paper supply portion 80 is equipped with a paper supply cassette 81 and a manual feed tray 82. The paper supply cassette 81 stores a plurality of sheets of paper for use in the image forming process and is provided below the exposure unit 9. The manual feed tray 82 is provided on a side of the image forming apparatus 100. The paper supply portion 80 supplies the sheets of paper one by one from the paper supply cassette 81 or the manual feed tray 82 to a sheet feed path 40. The sheet feed path 40 is formed to extend from the paper supply portion 80 to the paper discharge tray 91 by passing between the intermediate transfer belt 61 and the secondary transfer unit 30 and through the fixing unit 70.

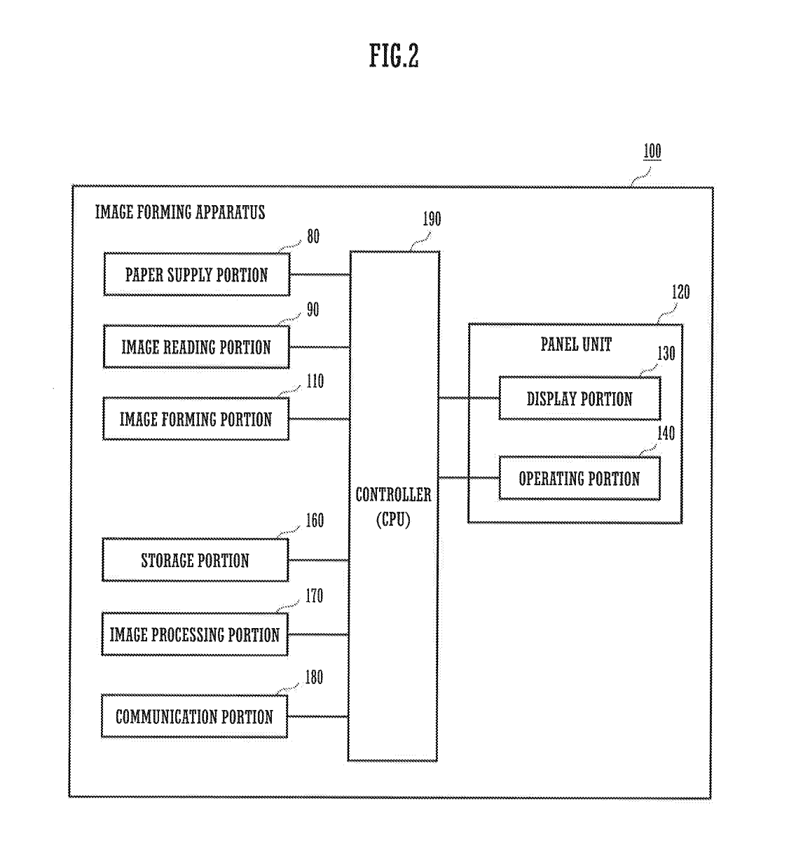

Subsequently, a description is made of a control system of the image forming apparatus 100. As shown in FIG. 2, the controller 190 of the image forming apparatus 100 respectively controls the paper supply portion 80, the image reading portion 90, the image forming portion 110, the display portion 130, the operating portion 140, a storage portion 160, an image processing portion 170, and the communication portion 180. The communication portion 180 receives image data that an external device has outputted.

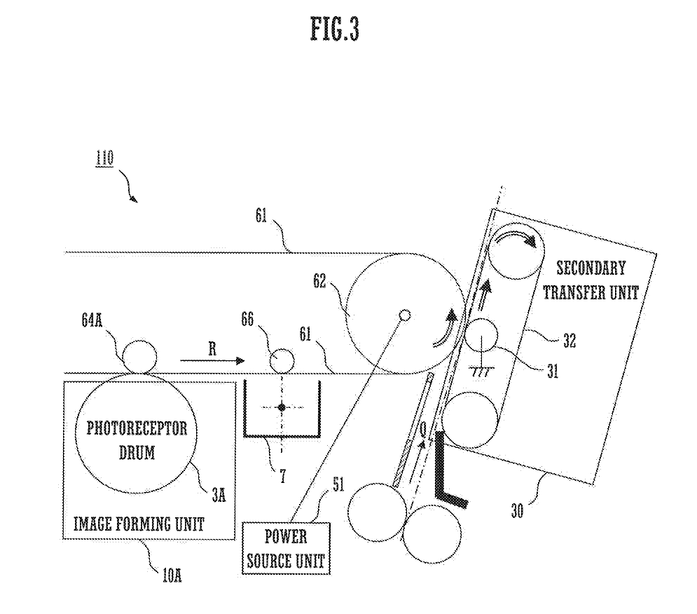

Then, a description is made of the power source unit that outputs a transfer voltage to the secondary transfer unit. As shown in FIG. 3, the power source unit 51 is connected to the driving roller 62. In addition, the secondary transfer roller 31 is grounded. The power source unit 51, when secondarily transferring the toner image on the intermediate transfer belt 61 onto the sheet of paper that has been fed to the secondary transfer position, outputs a transfer voltage as an output voltage to the driving roller 62. Moreover, the power source unit 51 outputs the transfer voltage before the execution of the secondary transfer in order to perform error detection of an output.

The transfer voltage is applied between the driving roller 62, the intermediate transfer belt 61, (the sheet of paper), the secondary transfer belt 32, and the secondary transfer roller 31. To the driving roller 62, a predetermined voltage value (transfer voltage) having a polarity the same as the polarity of the charged potential of toner is applied. The load seen from the power source unit 51 is a capacitive load. Therefore, when a voltage is applied to the load, the output voltage of the power source unit 51 varies at a constant gradient.

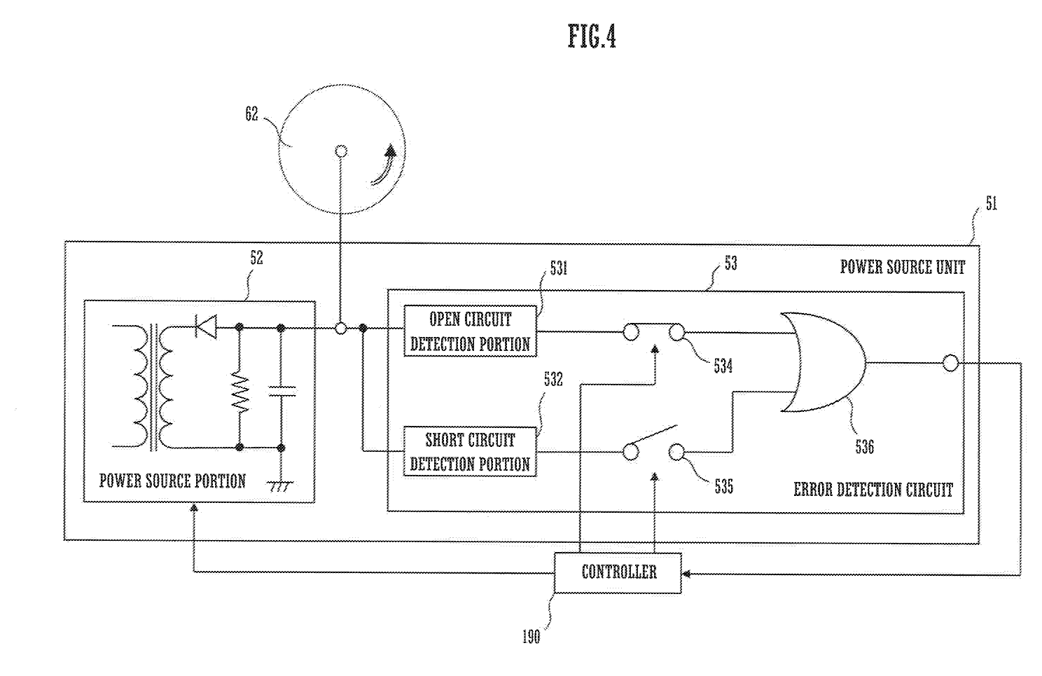

Subsequently, a description will be made of a first preferred embodiment of the present invention. As shown in FIG. 4, the power source unit 51 is equipped with a power source portion 52 and an error detection circuit 53. In addition, the error detection circuit 53 may preferably be equipped with an open circuit detection portion 531, a short circuit detection portion 532, a switch 534, a switch 535, and a logical sum element (hereinafter referred to as “OR gate”) 536 as a gate portion.

The output of the power source portion 52 is connected to the open circuit detection portion 531 and the short circuit detection portion 532 in addition to the driving roller 62. The output of the open circuit detection portion 531 is connected to one of the inputs of the OR gate 536 through the switch 534. The switch 534 as a first switch may preferably cause the open circuit detection portion 531 and the OR gate 536 to connect to or separate from each other. The output of the short circuit detection portion 532 is connected to the other of the inputs of the OR gate 536 through the switch 535. The switch 535 as a second switch may preferably cause the short circuit detection portion 532 and the OR gate 536 to connect to or separate from each other. The output of the OR gate 536 is connected to a signal input terminal of the controller 190.

The open circuit detection portion 531 detects whether the output of the power source portion 52 is in an open circuit state. If the output of the power source portion 52 is in the open (opening) state, a large current flows into the driving roller 62, so that the absolute value of the output voltage of the power source portion 52 becomes a very high value. The open circuit detection portion 531, when the absolute value of the output voltage of the power source portion 52 is more than or equal to a preset first threshold value (open circuit detection voltage threshold value), outputs an error signal (Hi signal) by determining the output of the power source portion 52 as being in the open circuit state. The open circuit detection portion 531 does not output an error signal when the absolute value of the output voltage of the power source portion 52 is less than the first threshold value. The first threshold value is −6 kV, for example.

The short circuit detection portion 532 detects whether the output of the power source portion 52 is in a short circuit state. If the output of the power source portion 52 is in the short circuit (short circuited) state, a current hardly flows into the driving roller 62, so that the absolute value of the output voltage of the power source portion 52 becomes a very low value. The short circuit detection portion 532, when the absolute value of the output voltage of the power source portion 52 is less than or equal to a preset second threshold value (short circuit detection voltage threshold value), outputs an error signal (Hi signal) by determining the output of the power source portion 52 as being in the short circuit state. The short circuit detection portion 532 does not output an error signal when the absolute value of the output voltage of the power source portion 52 is more than the second threshold value. The second threshold value is −200 V, for example.

The controller 190 controls the “open” and “close” of the switch 534 and the switch 535. In addition, the controller 190 outputs the output instruction signal (output instruction) of the transfer voltage to the power source portion 52. The controller 190, at a specific timing, outputs an output instruction signal to the power source portion 52 and causes the open circuit detection portion 531 and the short circuit detection portion 532 to execute a detection operation for detecting an error signal in this sequence. Specifically, the power source portion 52 starts the output of a voltage when an output instruction signal is inputted from the controller 190. The controller 190 monitors the output voltage value of the power source portion 52 by a not-shown voltmeter and the like, and, when the absolute value of the output voltage of the power source portion 52 is less than or equal to the second threshold value, switches the switch 534 to “close” and the switch 535 to “open” and detects an open circuit state. Moreover, the controller 190, when the absolute value of the output voltage of the power source portion 52 exceeds the second threshold value, switches the switch 534 to “open” and the switch 535 to “close” and detects a short circuit state.

The OR gate 536, when being inputted with an error signal (Hi signal) from the open circuit detection portion 531 or the short circuit detection portion 532, outputs a logical sum signal to the controller 190.

It is to be noted that, when the outputs of the open circuit detection portion 531 and the short circuit detection portion 532 are connected to the controller 190 without using the OP gate 536, two signal input terminals of the controller 190 are required. However, by using the OR gate 536, only one signal input terminal of the controller 190 may be required, and the other signal input terminal of the controller 190 can be used for the input of other signals. Accordingly, a CPU with a few signal input terminals can be used as the controller 190.

In the present invention, before image formation, the state check (error detection) of the output of the power source unit 51 is performed. As error detection, an open circuit state is first detected and then a short circuit state is continuously detected. More specifically, the detection of an open circuit state is performed during the rise of the output of the power source portion 52 whereas the detection of a short circuit state is performed after the output of the power source portion 52 exceeds the second threshold value during the rise of the output of the power source portion 52 or immediately after the rise of the output of the power source portion 52. This is because of the following reason.

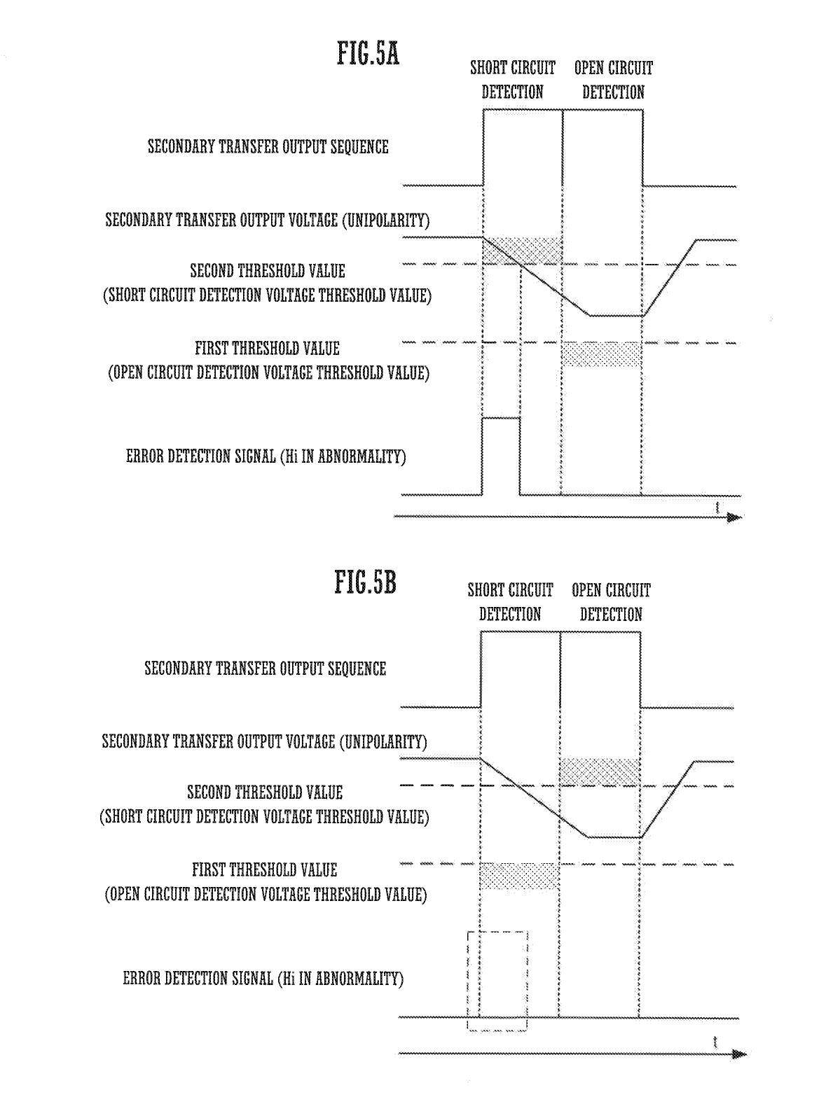

The power source portion 52 outputs a transfer voltage to the driving roller 62, the intermediate transfer belt 61, the secondary transfer belt 32, and the secondary transfer roller 31 that are loads, and, as is well known, these loads are capacitive loads. Therefore, since the rise time of the secondary transfer voltage as an output of the power source portion 52 varies according to the state of the load, the rise time may take long. At such a time, as shown in FIG. 5A, if the short circuit detection portion is caused to execute the detection operation for detecting the presence or absence of an error prior to the open circuit detection portion, in a case in which a time when the absolute value of the secondary transfer voltage is less than or equal to the second threshold value is long, there is a risk that the case may be erroneously detected as a short circuit state and an error signal may be outputted.

Therefore, in the present invention, as shown in FIG. 5B, the detection operation for detecting the presence or absence of an error of the open circuit detection portion is performed before the detection operation for detecting the presence or absence of an error of the short circuit detection portion. In addition, the detection operations for detecting the presence or absence of an error of the open circuit detection portion and the short circuit detection portion may preferably be continuously executed. At this time, after the output of the power source portion 52 exceeds the second threshold value, the detection operation for detecting the presence or absence of an error of the short circuit detection portion is performed. Thus, according to the state of the load, even when the rise time of the output voltage is long, the short circuit state is not erroneously detected. Accordingly, the open circuit state and the short circuit state of the power source portion can be correctly detected.

It should be noted that while FIGS. 5A and 5B, since a positive polarity toner is used in the image forming portion 110, show a case in which a negative value as the secondary transfer voltage is outputted from the power source portion 52, the present invention is naturally applicable to a configuration in which a negative polarity toner is used in the image forming portion 110 and a positive value as the secondary transfer voltage is outputted.

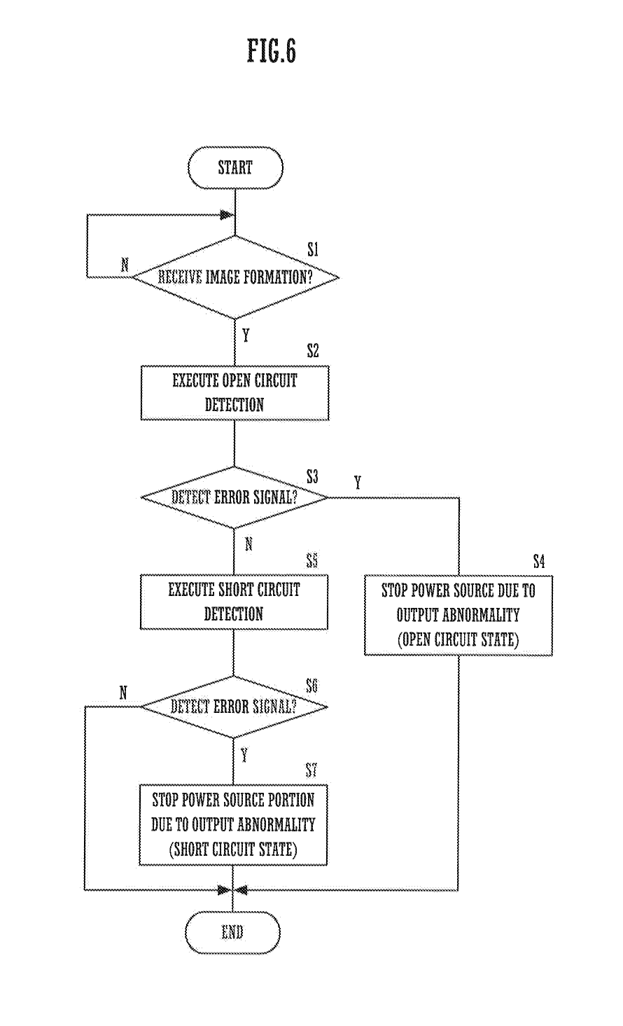

Subsequently, an error detection operation of the power source portion 52 will be described with reference to the flow chart shown in FIG. 6.

The controller 190 of the image forming apparatus 100 stands by until receiving an execution instruction of image formation (S1: N). At such a time, both the switch 534 and the switch 535 are in the state of “open”.

The controller 190, when receiving an execution instruction of image formation in the operating portion 140, or when receiving input of image data is from an externally connected device in the communication portion 180 as an execution instruction of image formation (S1: Y), outputs an output instruction signal to the power source portion 52 before the transfer portion transfers a toner image, and causes the open circuit detection portion 531 and the short circuit detection portion 532 to continuously execute the detection operation for detecting the presence or absence of an error. To begin with, the controller 190 executes open circuit detection of the output of the power source portion 52 (S2). Specifically, the controller 190 switches the switch 534 connected to the open circuit detection portion 531 to “close”. In addition, as shown in FIG. 5B, the controller 190 outputs an output instruction signal and causes the power source portion 52 to output a transfer voltage. It is to be noted that the switch 535 is kept in the state of “open”.

The controller 190, if detecting that an error signal has been outputted from the OR gate 536 (S3: Y), determines that the output of the power source portion 52 is abnormal, that is, that the output is in the open circuit state, and stops the power source portion 52. Moreover, the controller 190 does not perform an image forming operation and displays information that the image forming operation is not performed, on the display portion 130 (S4).

On the other hand, the controller 190, if an error signal is not outputted from the OR gate 536 (S3: N), continuously executes short circuit detection of the output of the power source portion 52 (S5). Specifically, the controller 190 switches the switch 534 connected to the open circuit detection portion 531 to “open” and switches the switch 535 connected to the short circuit detection portion 532 to “close”. Additionally, as shown in FIG. SB, the controller 190 causes the power source portion 52 to continuously output the transfer voltage. It should be noted that, if the output of the power source portion 52 is not in the open circuit state, the secondary transfer output voltage generally exceeds the second threshold value during execution of Step S2.

The controller 190, if detecting that an error signal has been outputted from the OR gate 536 (S6: Y), determines that the output of the power source portion 52 is abnormal, that is, that the output is in the short circuit state, and stops the power source portion 52. Moreover, the controller 190 does not perform the image forming operation and displays information that the image forming operation is not performed, on the display portion 130 (S7).

On the other hand, the controller 190, if an error signal is not outputted from the OP gate 536 (S6: N), ends the error detection process of the power source unit 51. Then the controller 190 performs image formation.

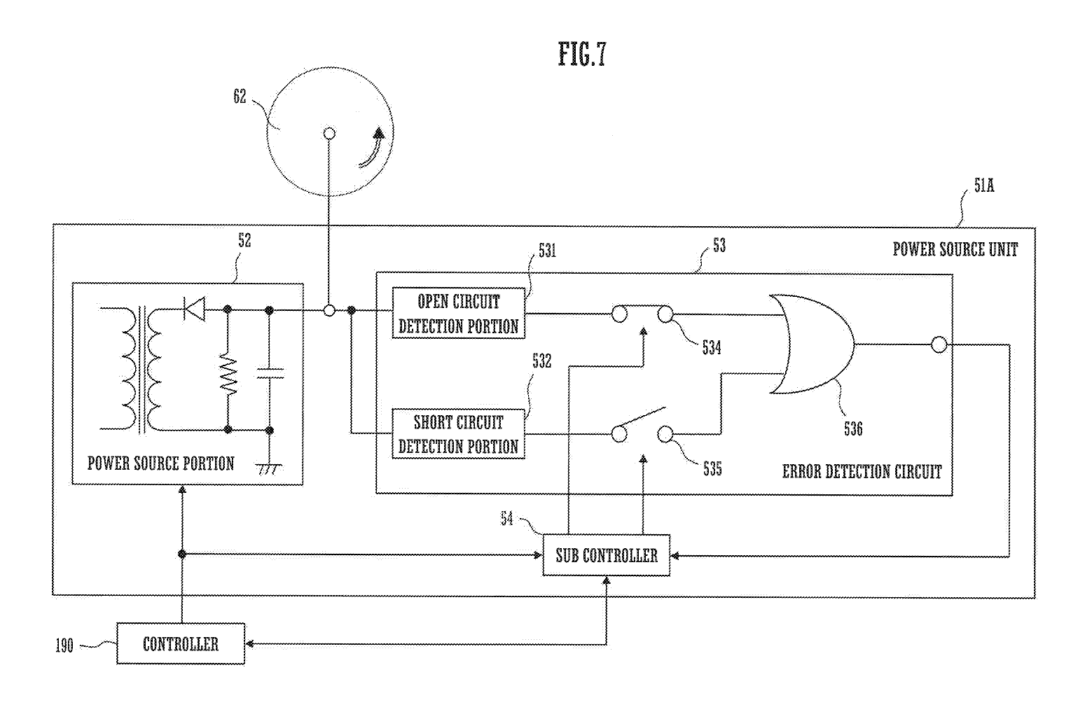

Subsequently, a description will be made of a second preferred embodiment of the present invention. The power source unit 51A shown in FIG. 7 has a configuration that is partially changed from the configuration of the power source unit 51 shown in FIG. 4, and the reference signs of only the changed part are changed. The differences between the power source unit 51A and the power source unit 51 are described.

The power source unit 51A is equipped with a sub controller 54. The sub controller 54 is connected to the controller 190, the switch 534, and the switch 535. Into the sub controller 54, an output instruction signal that the controller 190 outputs to the power source portion 52 is inputted. The sub controller 54 controls the “open” and “close” of the switch 534 and the switch 535 according to the value of this output instruction signal.

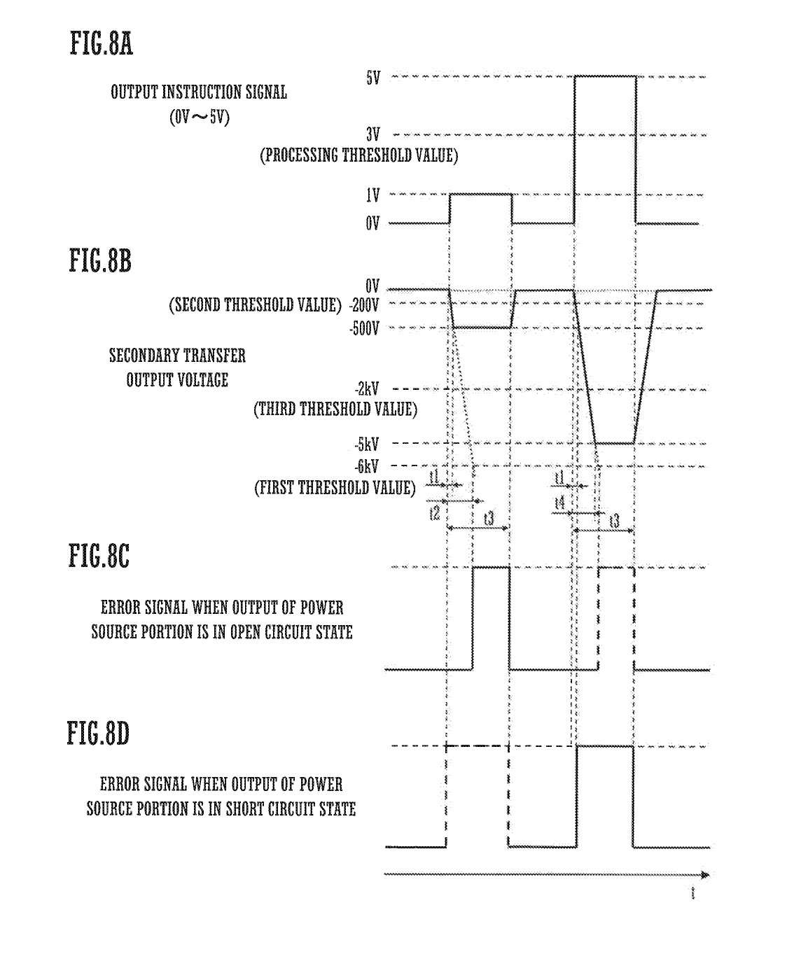

The controller 190 outputs an output instruction signal to the power source portion 52, and the power source portion 52 outputs a voltage according to the value of the output instruction signal. As an example, the power source portion 52 outputs the following voltage. Specifically, as shown in FIGS. 8A and 3B, the power source portion 52, when the value of the output instruction signal is 1 V, outputs a voltage of −500 V and, when the value of the output instruction signal is 5 V, outputs a voltage of −5 kV. In addition, the power source portion 52, when the value of the output instruction signal is 3 V as a processing threshold value, outputs −2 kV as a voltage of a third threshold value set up between the first threshold value (open circuit detection voltage threshold value (−6 kV)) and the second threshold value (short circuit detection voltage threshold value (−200 V)). It should be noted that the range of the value of the output instruction signal that the controller 190 outputs is 0 V to 5 V.

The output instruction signal that the controller 190 outputs is also inputted to the sub controller 54. The sub controller 54 controls the switch 534 and the switch 535 according to the value of the output instruction signal, and performs open circuit detection and short circuit detection. The sub controller 54, when the value of the output instruction signal is less than the processing threshold value (1 V, for example), executes the open circuit detection of the output of the power source portion 52. Specifically, the sub controller 54 switches the switch 534 to “close” and the switch 535 to “open” and checks the output of the open circuit detection portion 531.

In addition, the sub controller 54, when the value of the output instruction signal is more than or equal to the processing threshold value (5 V, for example), executes the short circuit detection of the output of the power source portion 52. Specifically, the sub controller 54 switches the switch 534 to “open” and the switch 535 “close” and checks the output of the short circuit detection portion 532. Thus, without measurement of the output voltage of the power source portion 52 with the use of a voltmeter and the like, the open circuit state and the short circuit state can be checked.

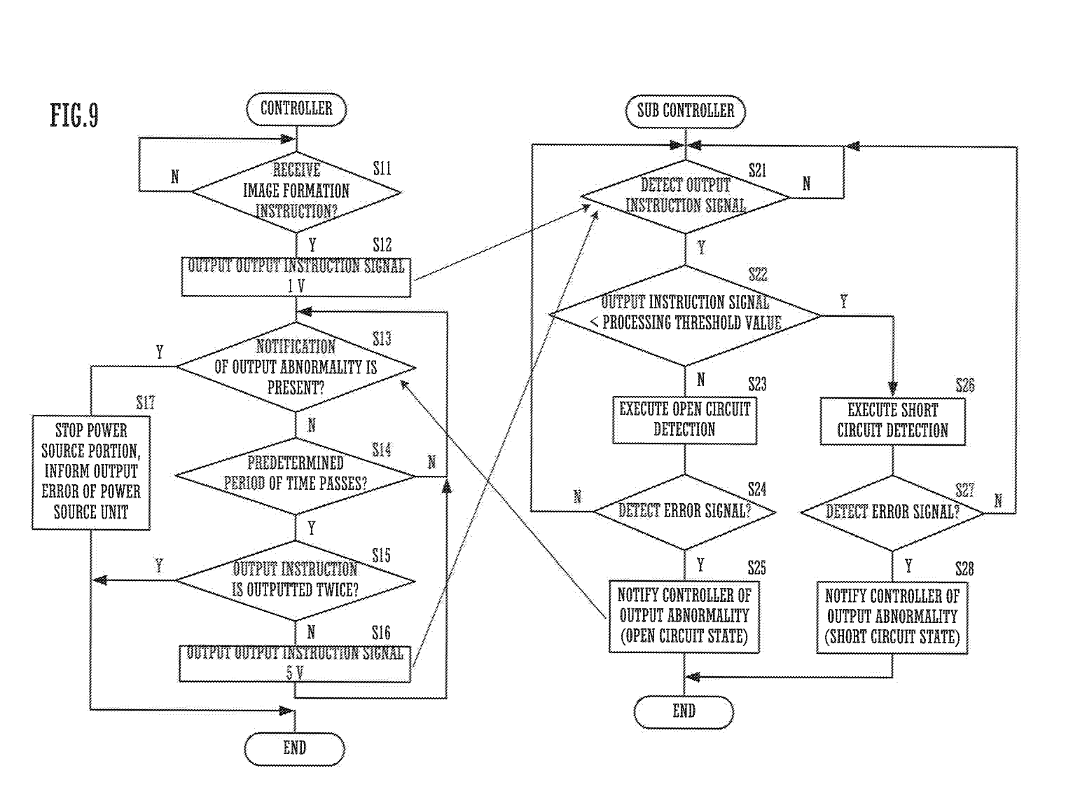

The power source unit 51A specifically performs the open circuit state and the short circuit state of the output of the power source portion 52, as follows. As shown in FIG. 9, the controller 190 of the image forming apparatus 100 stands by until receiving an execution instruction of image formation (S11: N).

The controller 190, when receiving an execution instruction of image formation in the operating portion 140, or when receiving input of image data is from an externally connected device in the communication portion 180 (11: Y), outputs an output instruction signal to the power source portion 52 before the transfer portion transfers a toner image. As shown in FIG. 9, the controller 190 outputs 1 V as an output instruction signal during a predetermined period of the time t3 (S12).

The power source portion 52, when being inputted with 1 V as an output instruction signal, outputs −500 V as a secondary transfer voltage to capacitive loads such as the driving roller 62. When the output of the power source portion 52 is normal, the secondary transfer voltage changes at a constant rate, and becomes −500 V after time t1 passes.

The sub controller 54 stands by until the controller 190 receives an execution instruction of image formation and outputs an output instruction signal (S21: N). At such a time, both the switch 534 and the switch 535 are in the state of “open”.

The sub controller 54, when detecting an output instruction signal that the controller 190 has outputted (S21: Y), performs a comparison between the value of the output instruction signal and the processing threshold value. The sub controller 54, in a case in which the value of the output instruction signal outputted in Step S12 is 1 V, which is less than 3 V as the processing threshold value (S22: N), executes the open circuit detection of the output of the power source portion 52. Accordingly, the switch 534 is switched to “close” and the switch 535 is left “open” (S23). In this state, the OR gate 536 is connected to only the open circuit detection portion 531, and the sub controller 54 can detect an error signal that the open circuit detection portion 531 outputs. It is to be noted that, in a case in which the output of the power source portion 52 is in an open circuit state, the output voltage exceeds the first threshold value after time t2 passes, and the error detection circuit 53 outputs an error signal.

The sub controller 54, as shown in FIG. 8C, if detecting an error signal by the time when the predetermined period of time t3 passes (S24: Y), notifies the controller 190 that the open circuit detection portion 531 has outputted the error signal (S25) and ends the process.

The controller 190, when being notified of the detection of the error signal (open circuit state) from the sub controller 54 (S13: Y), stops the power source portion 52, displays information that the output abnormality (open circuit state) has occurred in the power source unit 51 on the display portion 130 (S17), and ends the process.

On the other hand, the sub controller 54, if detecting no error signal even when the predetermined period of time t3 passes (S24: N), performs the process Step S21 again.

The controller 190, in Step S12, outputs 1 V as an output instruction signal, and then, if there is no notification of error signal detection from the sub controller 54 even when the predetermined period of time t3 passes (S14), and if the output instruction signal has not been outputted twice (S15: N), as shown in FIG. 8A, outputs 5 V, which is more than or equal to the processing threshold value, as an output instruction signal during the time t3 (S16). The power source portion 52, when being inputted with 5 V as an output instruction signal, outputs −5 kV as a secondary transfer voltage to capacitive loads such as the driving roller 62. When the output of the power source portion 52 is normal, the secondary transfer voltage changes at a constant gradient and becomes −5 kV after time t4 passes.

Then, the controller 190 waits for the notification of error signal detection from the sub controller 54 until the predetermined period of time t3 passes (S13: N, S14: N).

The sub controller 54, when detecting an output instruction signal that the controller 190 outputs (S21: Y), in a case in which the value of the output instruction signal is 5 V, which is more than or equal to 3 V as the processing threshold value (S22: Y), executes the short circuit detection of the output of the power source portion 52. Accordingly, the switch 534 is switched to “open” and the switch 535 to “close” (S26). In this state, only the short circuit detection portion 532 is connected to the OR gate 536, and the sub controller 54 can detect an error signal that the short circuit detection portion 532 outputs.

It should be noted that the sub controller 54, when performing short circuit detection, after detecting an output instruction signal, performs the detection after the time t1 passes. This is, as shown in FIGS. 8A and 8B, in a case in which the detection operations for detecting the presence or absence of an error of the open circuit detection portion and the short circuit detection portion are discontinuously executed, in order to prevent erroneous detection of a short circuit state during a period when the voltage that the power source portion 52 outputs to capacitive loads is less than or equal to the second threshold value (short circuit detection voltage threshold value).

In addition, the controller 190 can also cause the detection operations for detecting the presence or absence of an error of the open circuit detection portion and the short circuit detection portion to be continuously executed. Specifically, immediately after an output instruction signal 1 V is outputted and the predetermined period of time t3 passes, 5 V as an output instruction signal is outputted to make the voltage that the power source portion 52 outputs change from −500 V to −5 kV. Accordingly, when a short circuit state is checked, since the output voltage does not become 0 V once and the absolute value of the output voltage is more than or equal to the second threshold value, the detection of the short circuit state can be performed without waiting for the lapse of the time t1 as stated above.

The sub controller 54, as shown in FIG. 8D, when detecting an error signal while the output voltage of the power source portion 52 is continued to be less than or equal to the second threshold value (short circuit detection voltage threshold value) and by the time when the predetermined period of time t3 passes (S27: Y), notifies the controller 190 of information that the short circuit detection portion 532 has outputted an error signal (S28), and ends the process.

The controller 190, when being notified of the detection of the error signal (short circuit state) from the sub controller 54 (S13: Y), stops the power source portion 52, displays information that the output error (short circuit state) has occurred in the power source unit 51 on the display portion 130 (S17), and ends the process.

On the other hand, the controller 190, in Step S16, outputs 5 V as an output instruction signal, and then, if there is no notification of error signal detection from the sub controller 54 even when the predetermined period of time t3 passes (S14) and the output instruction signal has been outputted twice (S15: Y), determines that the output of the power source portion 52 is not an error state, and ends the process.

In this manner, according to a value of the output instruction signal that the controller 190 outputs to the power source portion 52, the open circuit state and the short circuit state of the output of the power source portion can also be detected.

It is to be noted that rise time t1, t2, and t4 of the output voltage of the power source portion 52 varies according to the state of the capacitive load. Therefore, the predetermined period of time t3 is set to a value with a margin with respect to the variation of the rise time.

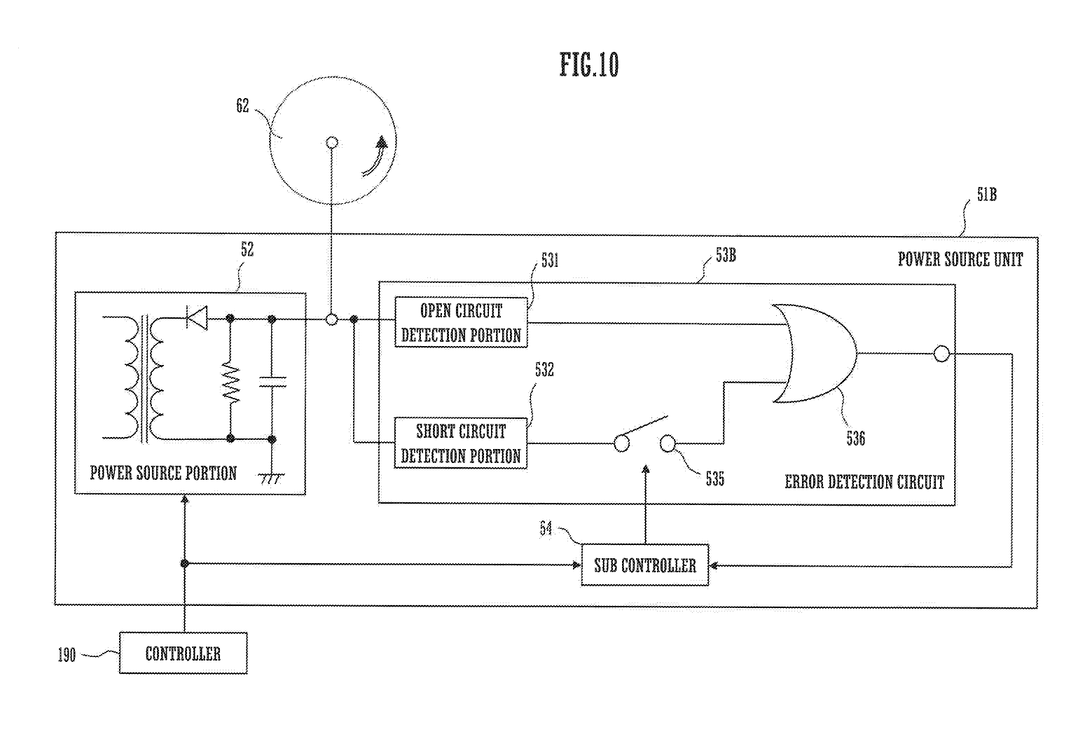

Subsequently, the error detection circuit, as shown in FIG. 10, can also be configured so that: the switch 534 is removed, the open circuit detection portion 531 and the OR gate 536 are directly connected to each other, and the short circuit detection portion 532 and the gate portion 536 are connected to or separated from each other by the switch 535.

In this configuration, like the power source unit 51A shown in FIG. 7, detections of an open circuit state and a short circuit state are performed in sequence.

More specifically, the controller 190, when receiving an execution instruction of image formation, first outputs an output instruction signal that is less than 3 V, and, if the power source unit 51B is not in the open circuit state, continuously outputs an output instruction signal that exceeds 3 V.

The power source portion 52, as described above, outputs a voltage of −500 V when the value of the output instruction signal is 3. V. In addition, the power source portion 52 outputs a voltage of −5 kV when the value of the output instruction signal is 5 V.

The sub controller 54, when the controller 190 outputs an output instruction signal that is less than or equal to 3 V, switches the switch 535 to “open” and performs the open circuit detection. Moreover, the sub controller 54, when the power source unit 51B is not in an open circuit state and the controller 190 outputs an output instruction signal that exceeds 3 V, switches the switch 535 to “close” and performs the short circuit detection.

Before the short circuit detection is performed, the state in which the output of the power source portion 52 is not open circuited is checked and the output of the power source portion 52 that is in the open circuit state is excluded, so that the open circuit detection portion 531 does not output an error signal. Therefore, when the switch 535 is switched to “close,” to the OR gate 536 inputted is only an error signal that, if the output of the power source portion 52 is in the short circuit state, the short circuit detection portion 532 outputs.

With such a configuration, the number of switches can be reduced and the control can be simplified.

As described above, in the image forming apparatus 100, the output of the power source portion 52 is checked before image formation; in a case in which an abnormality occurs, the execution of image formation is stopped; and only when no abnormalities occur, image formation is performed. Accordingly, in the power source portion 52, since the output is not in the open circuit state and thus a high no-load voltage does not occur, a design for enhancing insulation is unnecessary and the design cost and the cost of components can be reduced.

It should be noted that, while the above description is directed to a power source unit that outputs a transfer voltage for secondarily transferring a toner image, the present invention is not limited to such a power source unit but is also applicable to a not-shown power source unit that outputs a transfer voltage for transferring a toner image formed on each of the photoreceptor drums 3A to 3D onto the intermediate transfer belt 61.

In addition, the present invention can be applied to not only a power source unit that outputs the transfer voltage of an image forming apparatus but also a time when the output abnormality of a commonly used power source is detected.

Moreover, while FIG. 7 and FIG. 10 show the configuration in which a power source unit is equipped with a sub controller, the present invention is not limited to this configuration but can also be configured so that a power source unit may not be equipped with a sub controller and a controller may directly control an error detection circuit.

Furthermore, in the above description, while a positive polarity toner is used in the image forming apparatus and thus the polarity of the secondary transfer output voltage is set to negative, the present invention is not limited to this arrangement, and, when a negative polarity toner is used, the polarity of the secondary transfer output voltage can also be set to positive.

### REFERENCE SIGNS LIST

10A to 10D Image forming unit
30 Secondary transfer unit
31 Secondary transfer roller
32 Secondary transfer belt
51, 51A, 51B Power source unit
52 Power source portion
53, 53B Error detection circuit
54 Sub controller
60 Intermediate transfer unit
61 Intermediate transfer belt
62 Driving roller (load)
100 Image forming apparatus
110 Image forming portion
120 Panel unit
130 Display Portion
140 Operating Portion
180 Communication Portion
190 Controller
531 Open detection portion
532 Short detection portion
534, 535 Switch
536 Logical sum element (OR gate)

1: An error detection circuit comprising:
an open circuit detection portion that is connected to a power source portion outputting a voltage to a capacitive load and that outputs an error signal by determining an output of the power source portion is in an open circuit state when an absolute value of the voltage is more than or equal to a first threshold value;
a short circuit detection portion that is connected to the power source portion and that outputs an error signal by determining an output of the power source portion is in a short circuit state when the absolute value of the voltage is less than or equal to a second threshold value; and
a controller that outputs an output instruction signal to the power source portion to make the power source portion output the voltage and causes the open circuit detection portion and the short circuit detection portion to execute a detection operation for detecting presence or absence of an error in this sequence.

2: The error detection circuit according to claim 1, wherein the controller causes the open circuit detection portion and the short circuit detection portion to continuously execute the detection operation for detecting the presence or absence of an error.

3: The error detection circuit according to claim 1, wherein the controller causes the open circuit detection portion and the short circuit detection portion to discontinuously execute the detection operation for detecting the presence or absence of an error.

4: The error detection circuit according to claim 2, wherein the controller causes the open circuit detection portion to execute the detection operation when a voltage outputted to the capacitive load rises and causes the short circuit detection portion to execute the detection operation after the absolute value of the voltage exceeds the second threshold value when the voltage outputted to the capacitive load rises.

5: The error detection circuit according to claim 3,
wherein the power source portion outputs a voltage according to a value of the output instruction signal and outputs a voltage of a third threshold value set between the first threshold value and the second threshold value when the value of the output instruction signal is equal to a processing threshold value; and
wherein the controller causes the open circuit detection portion to execute the detection operation when the value of the output instruction signal is less than the processing threshold value and causes the short circuit detection portion to execute the detection operation when the value of the output instruction signal is more than or equal to the processing threshold value.

6: The error detection circuit according to claim 1, further comprising a gate portion that outputs a logical sum signal of an output of the open circuit detection portion and an output of the short circuit detection portion to the controller.

7: The error detection circuit according to claim 6, further comprising:
a first switch that causes the open circuit detection portion and the gate portion to connect to or separate from each other; and
a second switch that causes the short circuit detection portion and the gate portion to connect to or separate from each other, wherein
the controller controls the first switch and the second switch.

8: The error detection circuit according to claim 6, further comprising a switch that causes the short circuit detection portion and the gate portion to connect to or separate from each other, wherein the controller controls the switch.

9: A power source unit comprising:
the error detection circuit and the power source portion according to claim 1.

10: An image forming apparatus comprising:
an image forming portion that forms a toner image;
a transfer portion that transfers the toner image formed by the image forming portion to a recording medium; and
the power source unit according to claim 9 that outputs to the transfer portion a voltage as a transfer voltage used when the transfer portion transfers the toner image.

11: The image forming apparatus according to claim 10, wherein the controller outputs the output instruction signal before the transfer portion transfers the toner image.
